(19) United States
(12) Patent Application Publication
(10) Pub. No.: US 2018/0269091 A1
(43) Pub. Date: Sep. 20, 2018

(54) CHIP IDENTIFICATION SYSTEM

(71) Applicant: Elenion Technologies, LLC, New York, NY (US)

(72) Inventors: Noam Ophir, New York, NY (US); Xiaoliang Zhu, New York, NY (US); Ari Novack, New York, CA (US); Michael J. Hochberg, New York, NY (US)

(21) Appl. No.: 15/460,335

(22) Filed: Mar. 16, 2017

(51) Int. Cl. H01L 21/67; H01L 23/544

(52) U.S. Cl. CPC H01L 21/67294; H01L 23/544; H01L 2223/54413; H01L 2223/5442; H01L 2223/54433

(57) ABSTRACT

Otherwise-unused metal pads are utilized for mechanically marking an identification number on each chip in each reticle of each semiconductor wafer. A chip-specific marking pattern is scribed into selected metal pads using a standard commercial wafer probe controlled by a custom-built controller to direct the probe or probe stage to implement the pattern. Visual inspection (manual and automated) may then be used for die identification based on the probe-marked pattern, including incorporating the visual inspection of these pads into the product building process.

### FIELD OF THE INVENTION

The present invention relates to a chip identification system, and in particular to a chip identification system utilizing marked metal pads.

### BACKGROUND OF THE INVENTION

During fabrication a semiconductor wafer is divided into a plurality reticles, and each reticle is divided into a plurality of chips. As semiconductor chip fabrication processes become more accurate, and the individual chips become more specialized and complicated, there is a growing demand to identify particle features of each chip in each reticle on each wafer.

In conventional complementary metal oxide semiconductor (CMOS) fabrication processes, each chip may include a diode, which can be “burnt” by driving a high current therethrough, whereby each chip is encoded with a unique identification number. Then each diode may be probed by running an electrical test to detect open/short on each diode, thereby decoding the chip identification number. Unfortunately, this can be a costly procedure to incorporate, because many diodes are required to encode each chip with a unique identification number.

For group III-V semiconductors, wafer patterns can be etched unique to each reticle and chip using an E-Beam writer, thereby patterning an ID number into each part. However, since E-Beam tools are not used in standard CMOS manufacturing fabrication processes, this is not typically applicable for silicon semiconductor wafers.

### BRIEF DESCRIPTION OF THE DRAWINGS

FIG. 1 is a plan view of a wafer comprising a plurality of reticles.

FIG. 2 is a plan view of marked and unmarked pads in accordance with the present invention.

FIG. 3 is an of an isometric view of a semiconductor wafer on a probing station.

FIG. 4 is a side view of the probing station of FIG. 3.

FIG. 5 is a plan view of marked and unmarked pads in accordance with the present invention.

FIG. 6 is a plan view of marked and unmarked pads in accordance with another embodiment of the present invention.

FIG. 7 is a plan view of marked and unmarked pads with human readable labels in accordance with another embodiment of the present invention.

### DETAILED DESCRIPTION OF THE INVENTION

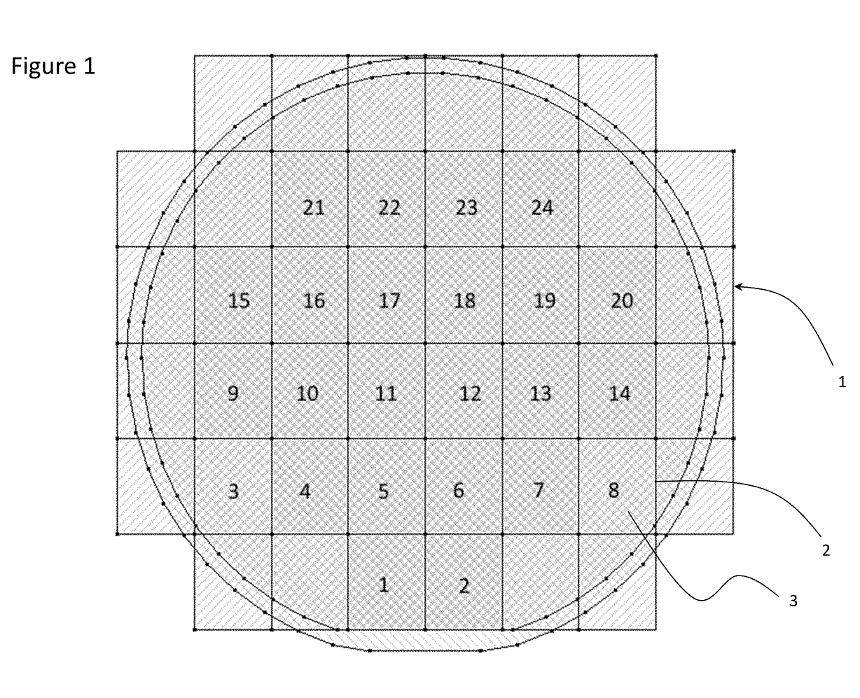

FIG. 1 illustrates an example layout of reticles 2 on a semiconductor, e.g., CMOS, wafer 1. Reticles 2 numbering 1 to 24 are duplicates of each other post fabrication. However, each reticle 2 may also contain multiple copies of chips 3. The method of the present invention enables the addition of identifiable information to each chip 3 outside of standard semiconductor, e.g., CMOS, processes.

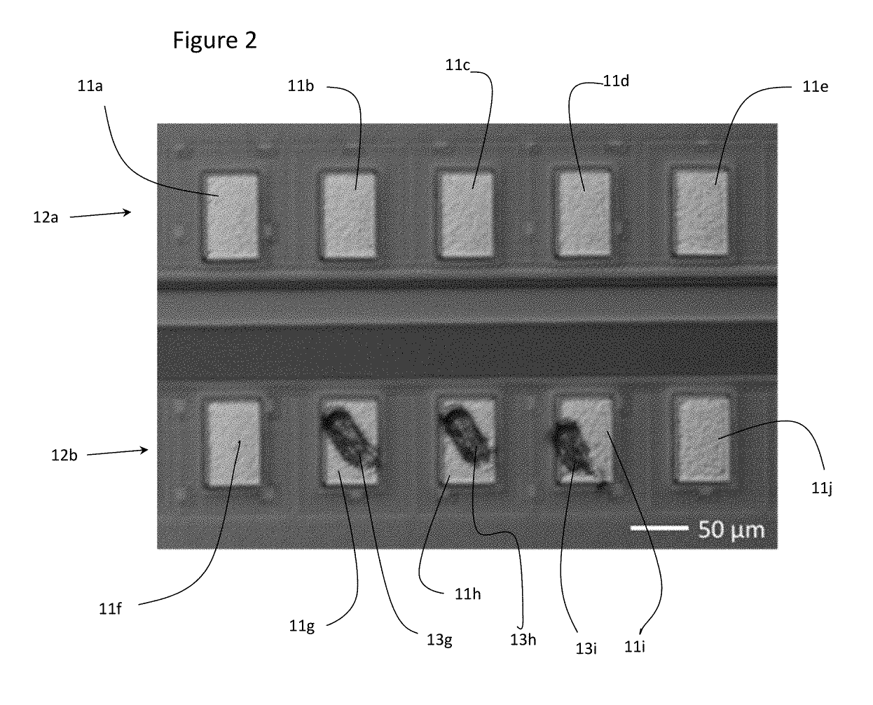

With reference to FIG. 2, a plurality of extra metal pads 11a to 11j (or collectively as just 11), preferably one or more arrays of metal pads, e.g., 1×N, 2×N, are provided on top of each chip 3 on the semiconductor wafer 1. The arrays of metal pads 11 may include a first row 12a of metal pads comprising at least eight, parallel metal pads 11. Preferably, the arrays of metal pads 11 also includes a second row of metal pads 12b comprising at least eight, parallel metal pads 11. Copper, aluminum, gold, and any other suitable metal pads are typically deposited on top of the semiconductor wafer 1 to provide electrical contacts between the components on each chip 3 and external electrical components, or leads. Typically, the metal pads 11a-11j are less than about 100 μm by about 100 μm, and preferably less than about 75 μm by about 75 μm, and ideally about 60 μm by about 40 μm. According to the present invention the extra metal pads 11 are provided as marking guides or place holders for an identification number. Just after fabrication the metal pads, e.g., 11a to 11e, have a smooth, mirror-like finish, as illustrated in the top row 12a of pads 11a to 11e in FIG. 2. However, selected pads 11g to 11i, may be marked with scribe marks 13g to 13i, as described hereinafter with additional identification information, as illustrated in the bottom row 12b of pads 11f to 11j.

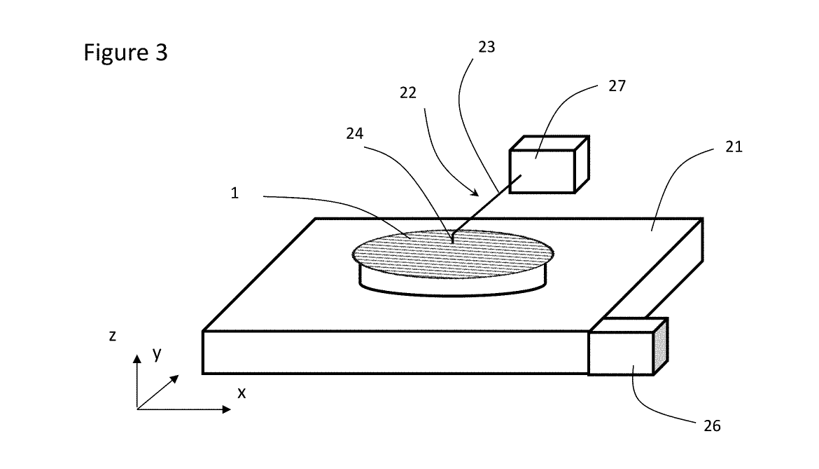

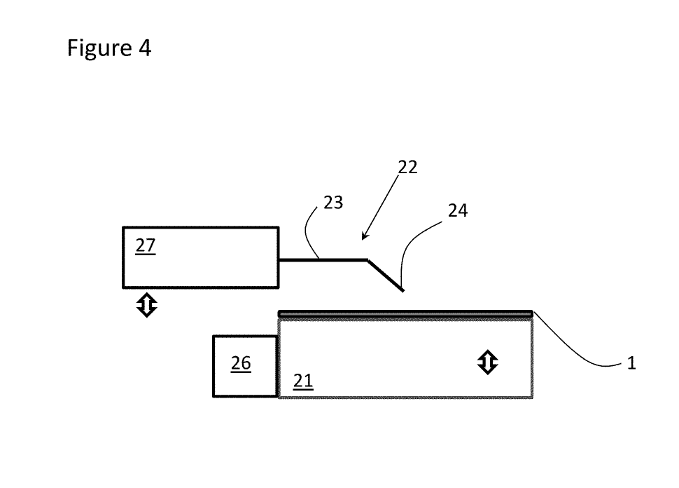

FIGS. 3 and 4 illustrate the method and apparatus for mechanically scribing identification information onto the wafer 1. The wafer 1 is loaded onto a probing station or mechanical stage 21 that is capable of movement in x, y, and z directions, and a needle-like probe 22, such as a conventional logic probe, is positioned above the wafer 1. The probe 22 is comprised of a probe arm 23 and a probe tip 24, which is comprised of metal hard enough to scratch the metal on the pads 11. The position of the mechanical stage 21 is controlled by control software stored in non-transitory memory and executable on a control processor 26. Alternatively, the probe 22 is moveable in the x, y, z directions and the position of the probe 22 is controlled by the control software stored in non-transitory memory and executable on a control processor 27. The x-y coordinates of each metal pad 11 to be marked is input into the control software. The coordinates of the metal pads 11 may be predetermined in accordance with a particular type of pad arrangement or wafer 1, which is mounted on the mechanical stage 21 in a predetermined orientation, e.g., with visual and/or mechanical alignment features on both the wafer 1 and mechanical stage 21 in alignment. Alternatively, the coordinates of the metal pads 11 may be determined by sensors in communication with the control processor 26 and/or 27. The sensors may be optical sensors detecting the reflective properties of the pads 11. Alternatively, the coordinates of the metal pads 11 are manually entered into the control processor 26 and/or 27.

The control software moves the x-y stage 21 (or the metal probe 22) so that the targeted metal pad 11 is under the probe 22, then pushes the wafer 1 up (or the probe 22 down) using the z-stage so that the probe tip 24 makes physical contact with the metal pad 11. Because the probe tip 24 has a greater hardness than the metal pad 11, and the probe arm 23 has a certain flexibility, the contact between the probe tip 24 and the metal pad 11 leaves a scratch mark, e.g., 13g to 13i. Ideally, the scratch mark comprises a straight diagonal scratch mark extending from proximate to one corner of the pad 11 to proximate to a diagonally opposed corner. However, scratch marks comprising other sizes and shapes will also work.

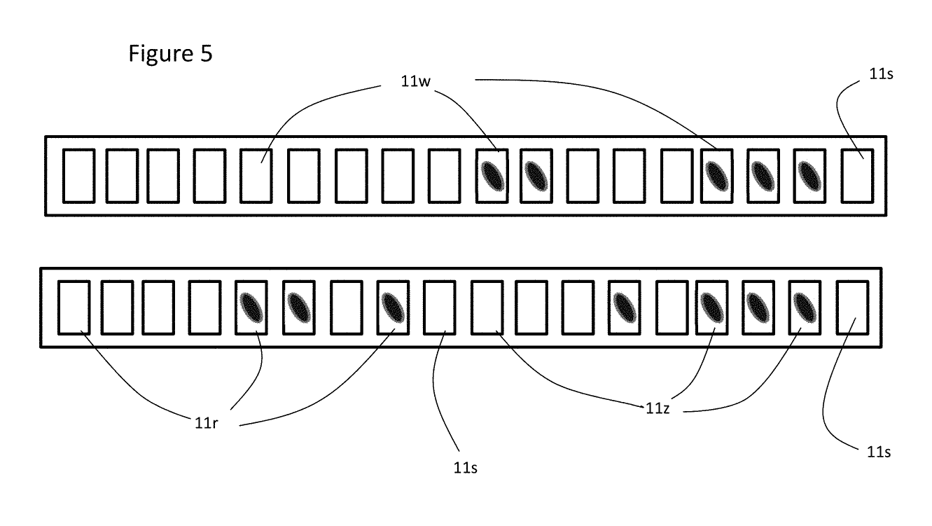

There are many different coding schemes that can be used to differentiate and/or identify the various chips 3, e.g. the position of the scratch 13 relative to other pads 11, the presence or absence of the scratch 13 or even the length and/or direction of the scratch 13. An added spacing between pads 11 may be indicative of simply a new number or some kind of punctuation or symbol, e.g., hyphen, period, bracket, comma, etc. An example is illustrated in FIG. 5, in which a binary encoding scheme is used for wafer number, reticle number, and chip number on two rows of unused pads 11. Each scratched pad 11 may be read as 1 and every un-scratched pad 11 may be read as 0. The first sixteen pads 11w on the top row represents a sixteen bit binary number corresponding to the specific wafer 1, e.g., wafer 199, and the seventeenth pad 11s is a spacer pad or bit. The first eight pads 11r on the lower row represent an eight bit binary number corresponding to the specific reticle 2, e.g., 13, followed by another spacer pad 11s, followed by eight pads 11z or bits corresponding to the specific chip 3, e.g., 23.The last pad 11s is another spacer pad. Either a human operator or machine vision can be used to decode the binary number encoded by the scratched pads 11w, 11r and 11z.

The encoded pattern per chip may define chip characteristics other than wafer, reticle, and chip number, e,g, fabrication lot number, a time stamp, or pass/fail test result. The information may then enable the manufacturer to verify inventory or perform binning at a later time.

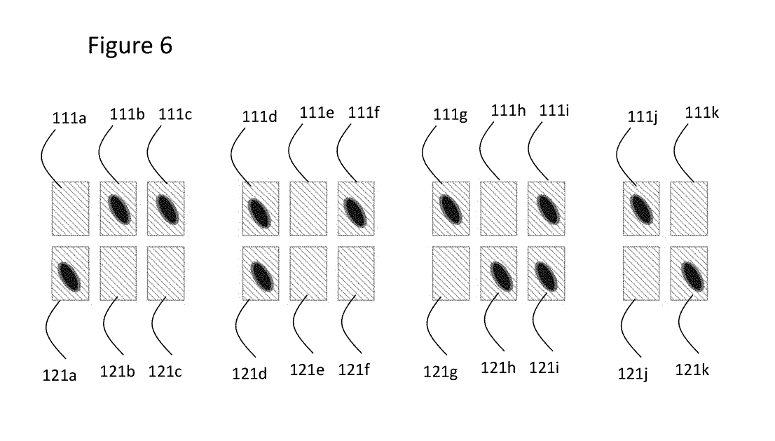

With reference to FIG. 6, a quad-encoding scheme may also be used to facilitate easier manual decoding. In the illustrated embodiment, in this 2×11 array of pads, there are eleven columns of two pads each 111a to 111k and 121a to 121k, representing a 22-bit binary number. More columns and rows are within the scope of the invention. Each column can be read as the following numbers: (0) no pad scratched; (1) only bottom pad scratched; (2) only top pad scratched; (3) both top and bottom pad scratched. The serial number decoded from the illustrated diagram can be easily read by a human or a machine as 122-302-213-21. Note any binary serial number can be encoded using this scheme.

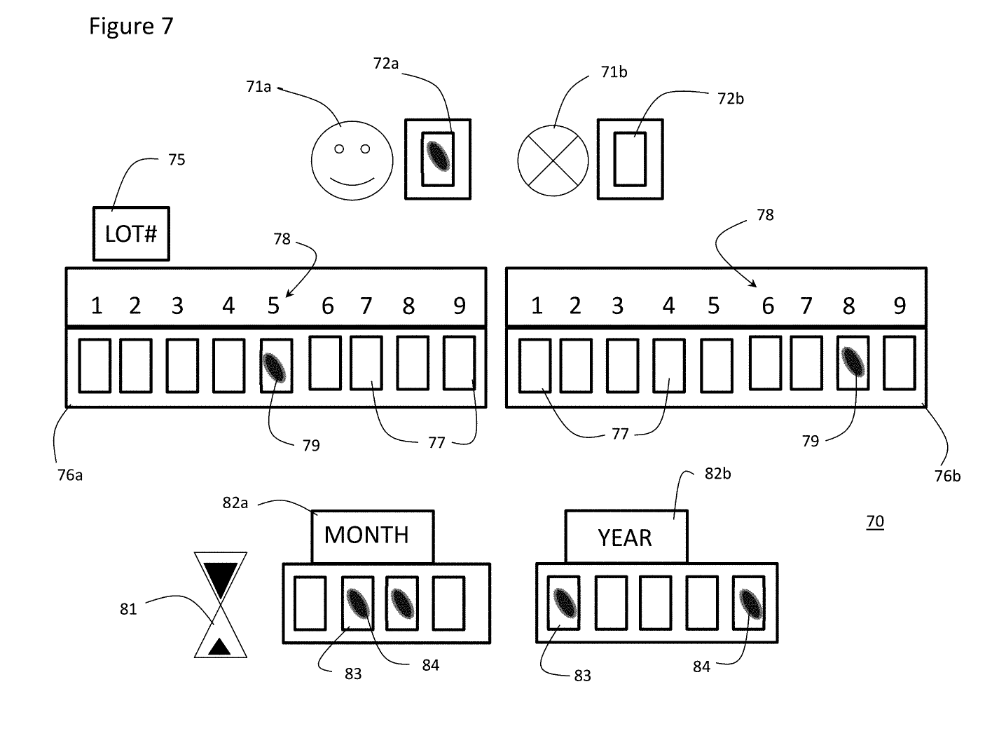

With reference to FIG. 7, to facilitate a more rapid decoding of the encoded patterns, human readable labels may be added adjacent to particular pads or arrays of pads indicating particular chip characteristics. The human readable labels may take the form of one or a series of ideograms, e.g., 71a and 71b, each adjacent a single pad 72a and 72b, respectively, whereby a yes/no, pass/fail or multiple choice question may be answered by simply scratching the corresponding pad 72a or 72b. In the illustrated embodiment, the pad 72a, corresponding to the affirmative ideogram 71a, is scratched indicating that the particular chip 70 has passed a preliminary test. A scratched pad 72b would have indicated that the particular chip 70 had failed the test.

The human readable label may also take the form of alpha-numeric symbols. In the illustrated embodiment, a label 75 is provided with one or more words and symbols indicating that the adjacent arrays of pads 76a and 76b are indicative of the lot number; however, other written labels and arrays of pads are also possible, e.g., for chip number, reticle number, wafer number. Each pad 77 may be provided with a corresponding number or symbol 78, e.g., numbers 1 to 9, whereby a scratch or plurality of scratches 79 on one or more pads 77 indicates a particular number or compound number, e.g., 58, corresponding to the particular scratches 79.

A combination of the aforementioned human readable and binary labels may also be used. For example: a ideogram 81, e.g., an hour glass, may be used to identify a general label, e.g., time stamp, and alpha-numeric labels 82a and 82b may be used to identify more specific headings, e.g., month and year. The pads 83 may include scratches 84 to indicate one or more binary numbers e.g., 6 and 17, corresponding to a particular month and year, e.g., June, 2017. Pads and arrays of pads may also be added for particular day and time, if required.

For this method of unique identification some surface area of each chip 3 has to be available for pads 11 to be used just for this application. Once the pads 11 are allocated, a marking code has to be determined to encode chip 3/reticle 2/wafer 1 identity.

The wafer 1 is then mounted on a mechanical stage 21 with a probe 22, one or both of which are moveable in the x, y and z directions. The particular numbers of each chip 3 are entered into the control processor 26 and/or 27. Furthermore, the particular positions of each of the available pads 11 are entered into or determined by the control processor 26 and/or 27. The position probe 22 or the mechanical stage 21 is or are repositioned by the control processor 26 and/or 27 so that the probe tip 24 in in contact with a pad 11 for marking to imprint the probe marks 13 on the chip 3 or wafer 1. This requires that the control software knows to receive the encoding input for the number of the chip 3 and the positions of the pads 11, and to translate that information to a sequence of positional commands for the probe 22.

After each chip 3 on the wafer 1 is encoded with a distinct number or symbol, the wafer 1 may be diced into individual reticles 2, and then into individual chips 3, as required.

For accurate identification of the chip 3, an imaging system may be needed. It can either be used by an operator manually decoding the patterns on a chip 3, or with an automated image recognition software that can differentiate between scratched and unscratched pads 11. The image recognition capability can be integrated into any handling/sorting/testing/assembly station to eliminate mislabeling of parts or eliminate the need to externally label parts. Accordingly, the specific capabilities, features, operating specifications, and location of each chip 3 may be stored, retrieved and tracked in a suitable database throughout the lifetime of the chip 3.

The present disclosure is not to be limited in scope by the specific example implementations described herein. Indeed, other implementations and modifications, in addition to those described herein, will be apparent to those of ordinary skill in the art from the foregoing description and accompanying drawings. Thus, such other implementation and modifications are intended to fall within the scope of the present disclosure. Further, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

1. An encoded semiconductor wafer comprising:
a semiconductor wafer including a plurality of reticles, each reticle comprising a plurality of chips; and
a plurality of designated metal pads on each chip for encoding, the designated metal pads comprising selected metal pads with a scribed marking, and other unmarked metal pads.

2. The encoded semiconductor wafer according to claim 1, further comprising a human readable label adjacent to at least one of the designated metal pads.

3. The encoded semiconductor wafer according to claim 1, wherein the human readable label comprises an ideogram corresponding to a chip characteristic.

4. The encoded semiconductor wafer according to claim 1, wherein the plurality of designated metal pads comprises an array of metal pads.

5. The encoded semiconductor wafer according to claim 4, wherein the array of metal pads comprises a binary encoded number, and wherein the selected metal pads correspond to a 1 and the unmarked metal pads correspond to a 0.

6. The encoded semiconductor wafer according to claim 5, wherein the array of metal pads includes a first row of at least eight metal pads corresponding to a binary number, a first group of metal pads designating the chip number, a second group of metal pads designating the reticle number, and a third group of metal pads designating the wafer number.

7. The encoded semiconductor wafer according to claim 6, wherein the array of metal pads also includes a second row of at least eight metal pads.

8. The encoded semiconductor wafer according to claim 4, wherein the array of metal pads comprises first and second rows of at least eight selected and unmarked metal pads corresponding to a quad-encoded number.

9. The encoded semiconductor wafer according to claim 1, wherein each metal pad comprises a length of less than 100 μm and width of less than 100 μm.

10. The encoded semiconductor wafer according to claim 1, wherein the scribed marking consists of a straight line.

11. A method of encoding individual chips on a semiconductor wafer during fabrication, comprising:
a) positioning the wafer on a probing stage;
b) positioning a probe over the wafer;
c) identifying designated metal pads on each chip on the semiconductor wafer for encoding, the designated metal pads comprising selected metal pads for marking and other metal pads to be left unmarked;
d) scribing a selected metal pad by adjusting the position of the probe and/or the probing stage to bring the probe into contact with one of the selected metal pads on one of the chips, thereby scribing the selected metal pad with an identifiable mark;
e) repeating step d) for each selected metal pad on the one chip;
f) repeating steps d) and e) for selected chip on the wafer.

12. The method according to claim 11, wherein the selected and other metal pads comprises a binary encoded number, and wherein the designated metal pads correspond to a 1 and the unmarked metal pads correspond to a 0.

13. The method according to claim 12, wherein the designated metal pads includes a first row of at least eight metal pads corresponding to the binary encoded number, a first group of metal pads designating the chip number, a second group of metal pads designating the reticle number, and a third group of metal pads designating the wafer number.

14. The method according to claim 11, wherein the designated metal pads includes first and second rows of at least eight metal pads; and wherein the designated metal pads comprises a quad-encoded number.

15. The method according to claim 11, wherein each metal pad comprises a length of less than 100 μm and width of less than 100 μm.

16. The method according to claim 11, wherein the step of scribing comprises scribing a straight line on the designated metal pad.

17. A system for encoding individual chips on a semiconductor wafer during fabrication, comprising:
a probing stage for supporting the semiconductor wafer including designated metal pads;
a probe with a tip having a hardness capable of scribing the designated metal pads; and
a controller capable of:
identifying designated metal pads on each chip on the semiconductor wafer for encoding, the designated metal pads comprising selected metal pads for marking and other metal pads to be left unmarked;
adjusting the position of the probe and/or the probing stage to bring the probe into contact with the selected metal pads on selected chips, thereby scribing the selected metal pads with an identifiable mark and leaving other designated metal pads unmarked.

18. The system according to claim 17, wherein the selected and other metal pads comprises a binary encoded number, and wherein the identifiable mark on the designated metal pads correspond to a 1 and the unmarked metal pads correspond to a 0.

19. The system according to claim 18, wherein the designated metal pads includes a first row of at least eight metal pads corresponding to the binary encoded number designating the chip number, the reticle number, and the wafer number.

20. The system according to claim 17, wherein the controller is capable of directing the probe and/or probing stage to scribe a straight line on the designated metal pad.
